(19) United States
(12) Patent Application Publication
(10) Pub. No.: US 2026/0190533 A1
(43) Pub. Date: Jul. 2, 2026

(54) PHOTOELECTRIC CONVERSION DEVICE

(71) Applicant: Japan Display Inc., Tokyo (JP)

(72) Inventor: Masumi NISHIMURA, Tokyo (JP)

(73) Assignee: Japan Display Inc., Tokyo (JP)

(21) Appl. No.: 19/407,062

(22) Filed: Dec. 3, 2025

(30) Foreign Application Priority Data
Dec. 26, 2024 (JP) 2024-229815

(51) Int. Cl. H10F 77/124; H10F 30/22; H10F 30/223; H10F 77/30

(52) U.S. Cl. CPC H10F 77/124; H10F 30/22; H10F 30/223; H10F 77/334

(57) ABSTRACT

A photoelectric conversion device includes an amorphous substrate, an orientation control layer on the amorphous substrate, and a photoelectric conversion structure disposed on the orientation control layer and comprising a crystalline III-V compound semiconductor.

### CROSS-REFERENCE TO RELATED APPLICATIONS

This application claims the benefit of priority to Japanese Patent Application No. 2024-229815, filed on Dec. 26, 2024, the entire contents of which are incorporated herein by reference.

### FIELD

An embodiment of the present invention relates to the structure of a photoelectric conversion device having a photoelectric conversion structure configured with a compound semiconductor.

### BACKGROUND

An infrared sensor is disclosed as a photoelectric conversion device having an n-type semiconductor layer, an i-type semiconductor layer, and a p-type semiconductor layer consisted of a crystalline III-V compound semiconductor stacked on a GaAs substrate (for example, refer to Japanese laid-open patent publication No. 2014-072217).

From the standpoint of a bandgap, crystalline III-V compound semiconductors are suitable for photoelectric conversion, for example for detecting infrared radiation. Such semiconductors are typically deposited by molecular beam epitaxy (MBE) or metal-organic chemical vapor deposition (MOCVD), and single-crystal substrates are used for crystal growth. Because single-crystal silicon and sapphire substrates are expensive, they are a factor that increases the manufacturing cost of infrared sensors as photoelectric conversion devices.

### SUMMARY

A photoelectric conversion device in an embodiment according to the present invention includes an amorphous substrate, an orientation control layer on the amorphous substrate, and a photoelectric conversion structure disposed on the orientation control layer and comprising a crystalline III-V compound semiconductor.

### BRIEF DESCRIPTION OF DRAWINGS

FIG. 1 is a cross-sectional view showing the structure of a photoelectric conversion device according to an embodiment of the present invention.

FIG. 2A is a cross-sectional view showing the structure of a photoelectric conversion device according to an embodiment of the present invention.

FIG. 2B is a cross-sectional view showing the structure of a photoelectric conversion device according to an embodiment of the present invention.

FIG. 3 is a cross-sectional view showing the structure of a photoelectric conversion device according to an embodiment of the present invention.

FIG. 4 is a cross-sectional view showing the structure of a photoelectric conversion device according to an embodiment of the present invention.

FIG. 5 is a cross-sectional view showing the structure of a photoelectric conversion device according to an embodiment of the present invention.

FIG. 6 is a cross-sectional view showing the structure of a photoelectric conversion device according to an embodiment of the present invention.

FIG. 7 is a cross-sectional view showing the structure of a photoelectric conversion device according to an embodiment of the present invention.

### DESCRIPTION OF EMBODIMENTS

Hereinafter, embodiments of the present invention are described with reference to the drawings. However, the present invention can be implemented in many different aspects and should not be construed as being limited to the description of the following embodiments. For the sake of clarifying the explanation, the drawings may be expressed schematically with respect to the width, thickness, shape, and the like of each part compared to the actual aspect, but this is only an example and does not limit the interpretation of the present invention. For this specification and each drawing, elements similar to those described previously with respect to previous drawings may be given the same reference sign (or a number followed by A, B, or the like) and a detailed description may be omitted as appropriate. The terms “first” and “second” appended to each element are a convenience sign used to distinguish them and have no further meaning except as otherwise explained.

As used herein, where a member or region is “on” (or “below”) another member or region, this includes cases where it is not only directly on (or just under) the other member or region but also above (or below) the other member or region, unless otherwise specified. That is, it includes the case where another component is included in between above (or below) other members or regions.

As used herein, the “photoelectric conversion structure” refers to a structure or laminate that converts light energy into electrical energy, and it includes a layer having any of the following semiconductor junction structures: a p-n junction, a p-i-n structure, or a Schottky junction.

As used herein, “substantially intrinsic” is not limited to a material evaluated as an intrinsic semiconductor that does not contain a conductive-type dopant. Rather, it denotes a state close to an intrinsic semiconductor that lacks dopants used to control the conductivity type, and may include a trace amount of a dopant that imparts n-type or p-type conductivity, so long as the layer functions as an intrinsic semiconductor. Such trace doping may also be referred to as weakly n-type or weakly p-type. Stated differently, “substantially intrinsic” refers to a carrier density of less than 1×10¹⁸/cm³, preferably less than 1×10¹⁵/cm³. In the following description, when a compound semiconductor layer is intrinsic or substantially intrinsic, it may be denoted as an i-type layer to distinguish it from n-type and p-type layers.

The configuration of a photoelectric conversion device according to an embodiment of the present invention is described below with reference to the drawings. The photoelectric conversion device according to an embodiment includes implementations having sensitivity in the infrared wavelength region.

### First Embodiment

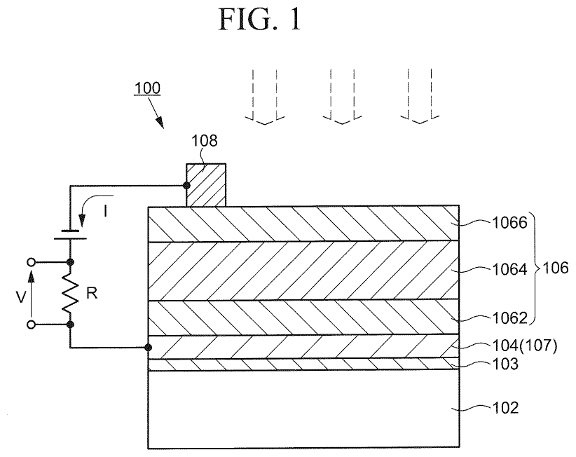

FIG. 1 is a cross-sectional view of a photoelectric conversion device 100 according to the present embodiment. The photoelectric conversion device 100 includes an orientation control layer 104 provided on an amorphous substrate 102, and a photoelectric conversion structure 106 provided on the orientation control layer 104. A base insulating layer 103 may be provided between the amorphous substrate 102 and the orientation control layer 104. A first electrode 107 and a second electrode 108 are provided so as to contact the photoelectric conversion structure 106. FIG. 1 illustrates a configuration where the orientation control layer 104 also serves as the first electrode 107, and the second electrode 108 is provided on the photoelectric conversion structure 106. The first electrode 107 and the second electrode 108 are in ohmic contact with the photoelectric conversion structure 106. Although not shown in FIG. 1, a passivation layer may be provided to cover the photoelectric conversion structure 106.

The photoelectric conversion structure 106 is formed of a crystalline III-V compound semiconductor (hereinafter, referred to simply as “compound semiconductor” unless otherwise noted). FIG. 1 illustrates a configuration where the photoelectric conversion structure 106 is formed of a first compound semiconductor layer 1062, a second compound semiconductor layer 1064, and a third compound semiconductor layer 1066. The first compound semiconductor layer 1062, the second compound semiconductor layer 1064, and the third compound semiconductor layer 1066 are stacked in this order from the side of the amorphous substrate 102.

The first compound semiconductor layer 1062 has a first conductivity type, the second compound semiconductor layer 1064 is intrinsic or substantially intrinsic, and the third compound semiconductor layer 1066 has a conductivity type opposite to the first conductivity type. For example, the first compound semiconductor layer 1062 may be n-type, and the third compound semiconductor layer 1066 may be p-type. Alternatively, the first compound semiconductor layer 1062 may have a p-type conductivity, and the third compound semiconductor layer 1066 may have an n-type conductivity. The photoelectric conversion structure 106 shown in FIG. 1 has the structure of a p-i-n diode in which the first compound semiconductor layer 1062, the second compound semiconductor layer 1064, and the third compound semiconductor layer 1066 having the conductivity types described above are stacked.

The photoelectric conversion device 100 operates with a bias voltage (reverse bias) applied between the first electrode 107 and the second electrode 108. When infrared light is incident on the photoelectric conversion device 100, photoelectric conversion occurs in the second compound semiconductor layer 1064, generating electrons and holes. Due to the applied bias voltage and the internal electric field, electrons drift toward the first electrode 107 and holes drift toward the second electrode 108. In a simple circuit configuration, when a load (resistor R) is connected between the first electrode 107 and the second electrode 108, a current I flows. The photoelectric conversion device 100 having a p-i-n structure exhibits low dark current (current in the absence of illumination) and can achieve a high response speed.

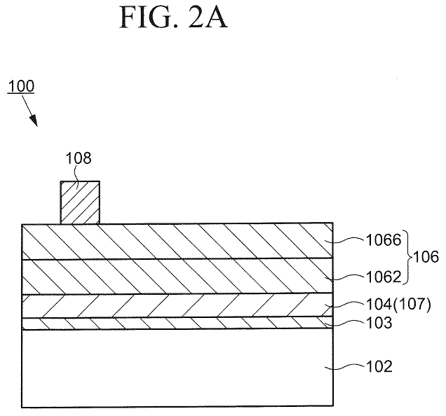

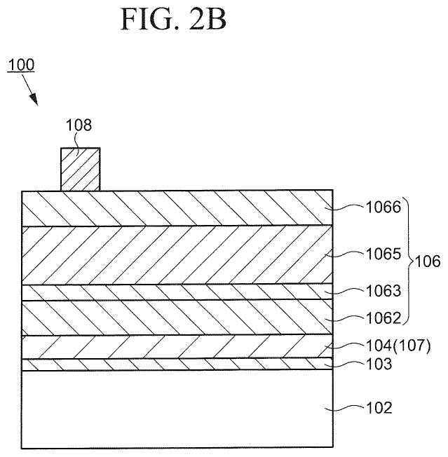

The photoelectric conversion structure 106 is not limited to the configuration shown in FIG. 1. As shown in FIG. 2A, the photoelectric conversion structure 106 may have the structure of a p-n junction diode in which the first compound semiconductor layer 1062 of one conductivity type and the third compound semiconductor layer 1066 of the opposite conductivity type are stacked. As shown in FIG. 2B, the photoelectric conversion structure 106 may have the structure of an avalanche photodiode in which a first compound semiconductor layer 1062 (n-type), a p-type compound semiconductor layer 1063, a p⁻-type compound semiconductor layer 1065, and a third compound semiconductor layer 1066 (p-type) are stacked. In this case, the p-type compound semiconductor layer 1063 functions as an electron-acceleration layer, and the p−type compound semiconductor layer 1065 functions as a light-absorption layer. The photoelectric conversion device 100 with this junction structure possesses amplification capabilities, enabling highly sensitive detection of faint light and achieving a high response speed.

While the amorphous substrate 102 lacks crystallinity, the respective compound semiconductor layers forming the photoelectric conversion structure 106 are crystalline. The orientation control layer 104 is interposed between the amorphous substrate 102 and the photoelectric conversion structure 106 and is provided to improve the crystallinity of the compound semiconductor layers of the photoelectric conversion structure 106.

The light-receiving surface of the photoelectric conversion device 100 can be the top side of the photoelectric conversion structure 106 (the side of the third compound semiconductor layer 1066). In addition, when the amorphous substrate 102 and the orientation control layer 104 are transparent to the wavelength of infrared light (i.e., transmit infrared light), the bottom side of the photoelectric conversion structure 106 (the side of the first compound semiconductor layer 1062) can serve as the light-receiving surface.

Thus, in this embodiment, the photoelectric conversion device 100 is configured with a photoelectric conversion structure 106, formed of compound semiconductor layers, on an amorphous substrate 102. The details of the components of the photoelectric conversion device 100 are described below.

### (1) Amorphous Substrate

The amorphous substrate 102 does not have a crystalline structure, has a coefficient of thermal expansion smaller than 50×10⁻⁷/° C., and has a strain point of 600° C. or higher. A glass substrate can be used as an amorphous substrate 102 satisfying these characteristics. Although various types of glass substrates are available, examples include a glass substrate formed of alumino-borosilicate glass and a glass substrate formed of aluminosilicate glass. It is preferable that the content of alkali metals such as sodium (Na) be 0.1% or less. Such glass substrates are used for liquid crystal displays and organic electroluminescence (organic EL) displays, and large-area “mother glass” substrates are commercially available. It is possible to increase the area by using such a glass substrate as the amorphous substrate 102, thereby enhancing the productivity of the photoelectric conversion device 100.

In addition to glass substrates, flexible resin substrates such as polyimide substrates, acrylic substrates, siloxane substrates, and fluor resin substrates may also be used as amorphous substrates 102.

### (2) Underlying Insulating Layer

As shown in FIG. 1, an underlying insulating layer 103 may be provided on the amorphous substrate 102 as an additional component. The underlying insulating layer 103 has either a single-layer structure of an inorganic insulating film or a stacked structure of multiple inorganic insulating films. Examples of the inorganic insulating film include a silicon nitride film, a silicon oxide film, a silicon oxynitride film, an aluminum nitride film, an aluminum oxide film, and an aluminum oxynitride film. For example, the underlying insulating layer 103 may have a stacked structure with a silicon nitride film and a silicon oxide film arranged in this order from the amorphous substrate 102 side. Preferably, the silicon nitride film used for the underlying insulating layer 103 has a thickness of 20 nm to 500 nm, and the silicon oxide film has a thickness of 20 nm to 500 nm.

When a glass substrate is used as the amorphous substrate 102, the glass substrate contains trace amounts of alkali metals (such as sodium). As a result, contamination of the photoelectric conversion structure 106 by alkali metals becomes an issue. To address this, providing the underlying insulating layer 103 prevents diffusion of alkali metals from the amorphous substrate 102 and prevents contamination of the photoelectric conversion structure 106. A silicon nitride film used as the underlying insulating layer 103 can block alkali metals when it has a thickness of 20 nm or greater.

The underlying insulating layer 103 can improve the adhesion of the orientation control layer 104. That is, it can prevent the orientation control layer 104 from peeling off the amorphous substrate 102. For example, by providing a silicon oxide film having a thickness of 20 nm or greater as the underlying insulating layer 103, delamination of the orientation control layer 104 can be prevented.

Thus, the underlying insulating layer 103 can serve both as a barrier layer against impurities and as a layer that improves the adhesion of the orientation control layer 104.

### (3) Orientation Control Layer

The orientation control layer 104 is provided to improve the crystallinity of the photoelectric conversion structure 106. While the amorphous substrate 102 lacks crystallinity, the orientation control layer 104 is crystalline.

The orientation control layer 104 can be selected from conductive materials and insulating materials. The orientation control layer 104 of the photoelectric conversion device 100 shown in FIG. 1 also functions as the first electrode 107. Therefore, the orientation control layer 104 is selected from among conductive materials. The orientation control layer 104 is further selected from materials that readily achieve lattice matching with the compound semiconductor material forming the photoelectric conversion structure 106. As described later, the photoelectric conversion structure 106 is formed of a compound semiconductor having photosensitivity in the infrared wavelength band. “Having photosensitivity” means that, when light of the above wavelength is irradiated onto a compound semiconductor film formed of a compound semiconductor material, photoconductivity is observed. To achieve lattice matching with such a compound semiconductor, it is preferable that the orientation control layer 104 have a lattice constant (value of a) in the range of 0.56 nm to 0.60 nm.

When the compound semiconductor layers forming the photoelectric conversion structure 106 have crystallinity with c-axis orientation, it is preferable that the orientation control layer 104 also be c-axis oriented. The crystals of the orientation control layer 104 preferably have rotational symmetry; for example, the crystal surface preferably exhibits sixfold symmetry. The crystalline structure of the orientation control layer 104 preferably has a hexagonal close-packed structure, a face-centered cubic structure, or a structure equivalent thereto. A structure equivalent to the hexagonal close-packed structure or the face-centered cubic structure includes a crystal structure in which the c-axis is not 90 degrees to the a-axis and b-axis. The orientation control layer 104 having a hexagonal close-packed structure or a structure equivalent thereto is preferably oriented in the (0001) direction, or c-axis direction, relative to the surface of the amorphous substrate 102 (this orientation state is also called (0001) orientation of the hexagonal-most-dense structure). The orientation control layer 104 having a face-centered cubic structure or equivalent structure should be oriented in the (111) direction with respect to the surface of the amorphous substrate 102 (this orientation state is also referred to as (111) orientation of the face-centered cubic structure).

The orientation control layer 104 preferably has high surface flatness. Expressed as arithmetic average roughness (Ra), the Ra is preferably less than 2.5 nm, and more preferably less than 2.3 nm. The arithmetic average roughness (Ra) is a value measured by atomic force microscopy (AFM). It is possible to enhance the crystallinity of the compound semiconductor layer that forms the photoelectric conversion structure 106 by having the orientation control layer 104 have a flat surface.

To improve flatness, the thickness of the orientation control layer 104 is preferably 5 nm to 500 nm, and more preferably 10 nm to 200 nm. The thickness can be measured with a contact profilometer or an optical film thickness meter (ellipsometry) and can also be determined from images obtained by a scanning electron microscope (SEM) or a transmission electron microscope (TEM). With a thickness within this range, the orientation control layer 104 attains higher surface flatness, thereby improving the crystallinity of the compound semiconductor layers forming the photoelectric conversion structure 106.

The orientation control layer 104 can be formed from various materials. Crystals of silicon (Si), germanium (Ge), antimony (Sb), and mixed crystals consisting of two or more of these elements can be used as the orientation control layer 104. Aluminum nitride (AlN), gallium nitride (GaN), indium nitride (InN), or mixed crystals in which these materials are mutually soluble may also be used as the orientation control layer 104. Further examples include zirconium (Zr), scandium (Sc), hafnium (Hf), magnesium (Mg), and zinc oxide (ZnO). Additionally, graphene, nickel (Ni), and titanium (Ti) can be used.

The orientation control layer 104 may be a single layer or may have a stacked structure of multiple layers. The orientation control layer 104 can be formed on the amorphous substrate 102 by, for example, sputtering or vacuum deposition. The orientation control layer 104 may also be formed by chemical vapor deposition (CVD) or atomic layer deposition (ALD).

### (4) Photoelectric Conversion Structure

The photoelectric conversion structure 106 is formed of a compound semiconductor material having photosensitivity to infrared light at wavelengths of 0.75 μm or greater, preferably 1.0 μm or greater, more preferably 1.3 μm or greater, and still more preferably 1.6 μm or greater. Stated differently, the compound semiconductor forming the photoelectric conversion structure 106 preferably has a bandgap of 1.66 eV or less, more preferably 1.24 eV or less, further preferably 0.95 eV or less, and still more preferably 0.78 eV or less, and exhibits photosensitivity to infrared light.

As shown in FIG. 1, when the photoelectric conversion structure 106 has a stacked configuration of the first compound semiconductor layer 1062 (n-type), the second compound semiconductor layer 1064 (i-type), and the third compound semiconductor layer 1066 (p-type), it is preferable that at least the second compound semiconductor layer 1064 exhibit photosensitivity to infrared light.

The compound semiconductor forming the photoelectric conversion structure 106 is preferably lattice-matched to the orientation control layer from the standpoint of mitigating lattice mismatch. As shown in FIG. 1, when the photoelectric conversion structure 106 has a stacked configuration of a first compound semiconductor layer 1062 (n-type), a second compound semiconductor layer 1064 (i-type), and a third compound semiconductor layer 1066 (p-type), it is preferable that at least the first compound semiconductor layer 1062 be lattice-matched to the orientation control layer. The first compound semiconductor layer 1062 formed as the first layer on top of the orientation control layer 104 is crystalline, so that the second compound semiconductor layer 1064 and the third compound semiconductor layer 1066 formed on top of it can also be crystalline.

Aluminum (Al), gallium (Ga), and indium (In), which are group 13 elements in the periodic table, and nitrogen (N), phosphorus (P), arsenic (As), and antimony (Sb), which are group 15 elements in the periodic table, can be used as III-V compound semiconductor materials. InGaAs, InAsN, InAsP, InGaN, GaAsP, InAsN, GaAsSb, and InN can be exemplified as III-V compound semiconductors composed of these elements. These III-V compound semiconductors can have a band gap below 1.66 eV, preferably below 1.24 eV, more preferably below 0.95 eV, and even below 0.78 eV by controlling the composition ratio of the elements. It is preferable that the orientation control layer 104 be formed by appropriately selecting from the materials exemplified above so as to achieve lattice matching with such crystalline III-V compound semiconductors.

The conductivity type (n-type or p-type) of crystalline III-V compound semiconductors can be controlled by adding dopants. Examples of n-type dopants include one or more elements selected from silicon (Si) and germanium (Ge). Examples of p-type dopants include one or more elements selected from magnesium (Mg), zinc (Zn), cadmium (Cd), and beryllium (Be).

In this embodiment, the photoelectric conversion structure 106 (first compound semiconductor layer 1062, second compound semiconductor layer 1064, and third compound semiconductor layer 1066) is formed, for example, by sputtering. During sputtering, the substrate temperature (set temperature) is controlled in the range of 100° C. to 650° C. Since the first compound semiconductor layer 1062, formed as the first layer, is provided on the orientation control layer 104, heteroepitaxial-like growth can be achieved even at substrate temperatures of 650° C. or lower, thereby promoting crystallization.

The sputtering target mounted in the sputtering apparatus is selected as appropriate according to the composition of the compound semiconductor layer to be deposited. For example, a sintered body of a crystalline III-V compound semiconductor can be used as the sputtering target. The first compound semiconductor layer 1062, the second compound semiconductor layer 1064, and the third compound semiconductor layer 1066 may be formed from crystalline III-V compound semiconductors of the same composition, or they may be formed from mutually different crystalline III-V compound semiconductors. Since the dopant species differ between the first compound semiconductor layer 1062 and the third compound semiconductor layer 1066, it is preferable to form these layers using different sputtering targets. In the configuration of the photoelectric conversion structure 106 shown in FIG. 1, the bandgap of the first compound semiconductor layer 1062 or the third compound semiconductor layer 1066 disposed on the light-incident side is preferably larger than the bandgap of the second compound semiconductor layer 1064. This arrangement reduces optical absorption loss by the first or third compound semiconductor layers disposed on the light-incident side, thereby improving the sensitivity of the photoelectric conversion device 100.

Argon (Ar) or a mixed gas of argon (Ar) and nitrogen (N₂) is used as the gas introduced during sputter deposition (sputter gas). The sputtering apparatus may be, for example, a diode sputtering apparatus, a magnetron sputtering apparatus, a dual-magnetron sputtering apparatus, a facing-target sputtering apparatus, an ion-beam sputtering apparatus, or an inductively coupled plasma (ICP) sputtering apparatus.

There is no limitation on the thicknesses of the first compound semiconductor layer 1062, the second compound semiconductor layer 1064, and the third compound semiconductor layer 1066. The first, second, and third compound semiconductor layers only need a thickness sufficient to form a p-i-n structure. Within the photoelectric conversion structure 106, infrared light is absorbed mainly by the second compound semiconductor layer 1064. Accordingly, the second compound semiconductor layer 1064 preferably has a thickness of 500 nm to 15000 nm to absorb infrared light.

### (5) First Electrode and Second Electrode

The photoelectric conversion device 100 shown in FIG. 1 has a second electrode 108 on top of the third compound semiconductor layer 1066. The second electrode 108 may be formed of a metallic material that forms an ohmic contact with the third compound semiconductor layer 1066, and it may alternatively be formed using another metallic material. When the third compound semiconductor layer 1066 is p-type, for example, gold (Au) or a gold alloy may be used as the second electrode 108; examples of the gold alloy include a gold-zinc (Au—Zn) alloy and a gold-antimony (Au—Sb) alloy.

The photoelectric conversion device 100 shown in FIG. 1 has an orientation control layer 104 that also serves as the first electrode 107. Accordingly, the orientation control layer 104 may be formed of a conductive material capable of forming an ohmic contact with the first compound semiconductor layer 1062, although other conductive materials may also be used. Examples of the orientation control layer 104 serving as the first electrode 107 include nickel (Ni), titanium (Ti), and zinc oxide (ZnO).

The photoelectric conversion device 100 of the present embodiment has a configuration with the photoelectric conversion structure 106 provided on the amorphous substrate 102. The photoelectric conversion structure 106 is formed of a crystalline III-V compound semiconductor and can exhibit photosensitivity in the infrared wavelength band, enabling it to be used as an infrared sensor. It is possible to provide a photoelectric conversion device 100 with high sensitivity and low noise by forming the photoelectric conversion structure 106 with a III-V compound semiconductor having crystalline properties. Moreover, since the amorphous substrate 102 is less expensive than single-crystal substrates such as sapphire and supports large-area formats, the productivity of the photoelectric conversion device 100 can be improved and overall cost can be reduced.

### Second Embodiment

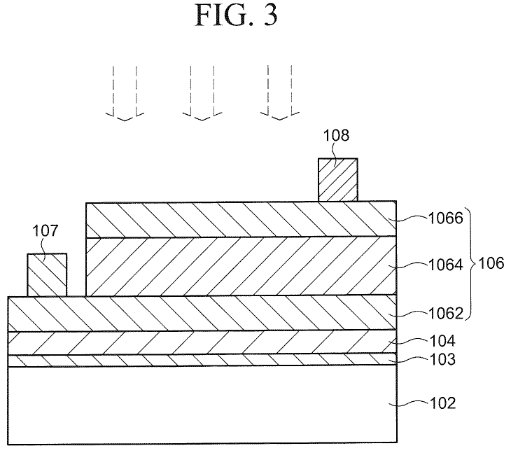

FIG. 3 is a cross-sectional view of a photoelectric conversion device 100 according to the present embodiment. The photoelectric conversion device 100 of the present embodiment differs from the first embodiment in the configuration of the first electrode 107. The following description focuses on differences from the first embodiment, and descriptions common to both embodiments are omitted as appropriate.

The photoelectric conversion device 100 shown in FIG. 3 has a configuration where a portion of the photoelectric conversion structure 106 is etched. Specifically, within the photoelectric conversion structure 106, portions of the third compound semiconductor layer 1066 and the second compound semiconductor layer 1064 are removed to define a region exposing the first compound semiconductor layer 1062. The first electrode 107 is provided in the exposed region of the first compound semiconductor layer 1062. The first electrode 107 is formed of a material that forms an ohmic contact with the first compound semiconductor layer 1062. Examples include metallic materials such as titanium (Ti) and gold (Au), and metal-oxide materials such as zinc oxide (ZnO). The first electrode 107 may have a stacked structure of multiple conductive materials; in that case, it is preferable that the layer contacting the first compound semiconductor layer 1062 be formed of the above metallic or metal-oxide materials.

The orientation control layer 104 may be formed of a conductive material or an insulating material. For example, the orientation control layer 104 can be formed of aluminum nitride (AlN). Since the aluminum nitride is transparent to infrared light, the amorphous substrate 102 side can serve as the light-receiving surface.

Except for the configuration of the first electrode 107, the photoelectric conversion device 100 according to the present embodiment is the same as the device of the first embodiment and can exhibit similar operational effects. Since the first electrode 107 and the second electrode 108 are provided on the same side (the side of the photoelectric conversion structure), the photoelectric conversion device 100 is suitable for surface mounting.

### Third Embodiment

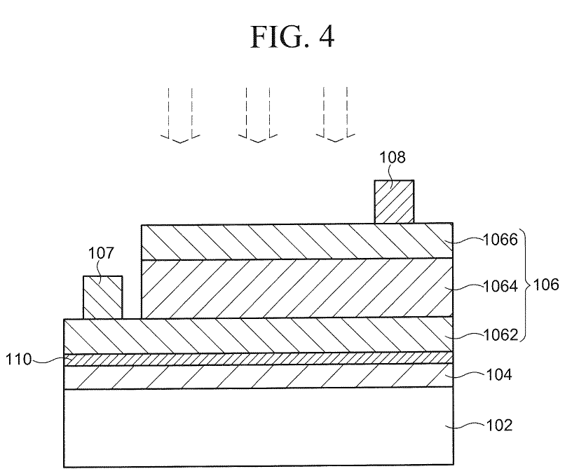

FIG. 4 is a cross-sectional view of a photoelectric conversion device 100 according to the present embodiment. Relative to the configuration of the second embodiment, the photoelectric conversion device 100 of the present embodiment has a structure with a high-resistance layer 110 additionally inserted between the orientation control layer 104 and the photoelectric conversion structure 106. The following description focuses on differences from the second embodiment, and descriptions common to both are omitted as appropriate.

It is preferable that the high-resistance layer 110 have a lattice constant comparable to that of the orientation control layer 104. That is, the lattice constant (value of a) of the high-resistance layer 110 is preferably in the range of 0.56 nm to 0.60 nm. Although no particular limitation is imposed on the resistivity of the high-resistance layer 110, it preferably has a resistivity of 1×10⁶ Ω cm, more preferably 1×10⁷ Ω cm. With such resistivity, the photoelectric conversion structure 106 can be electrically insulated from the orientation control layer 104 even when the orientation control layer 104 is conductive.

Indium phosphide (InP) can be used as the high-resistance layer 110. The indium phosphide (InP) employed for the high-resistance layer 110 preferably contains impurities such as iron (Fe), silicon (Si), sulfur(S), and zinc (Zn); adding such impurities renders the layer highly resistive.

Although indium phosphide (InP) is a crystalline III-V compound semiconductor, its bandgap is about 1.35 eV, so it is not suitable for use as the photoelectric conversion structure of an infrared sensor. However, because InP has a lattice constant of 0.5869 nm, it is well suited for lattice matching with materials such as InGaAs used for the photoelectric conversion structure 106, thereby improving crystallinity.

The photoelectric conversion device 100 of the present embodiment can insulate the photoelectric conversion structure 106 from the orientation control layer 104 even when the orientation control layer 104 is conductive by providing a high-resistance layer 110 between the orientation control layer 104 and the photoelectric conversion structure 106. Moreover, using a high-resistance layer 110 having a lattice constant in the range of 0.56 nm to 0.60 nm improves the crystallinity of the photoelectric conversion structure 106 regardless of the condition of the orientation control layer 104. Except for the provision of the high-resistance layer 110, the configuration of the photoelectric conversion device 100 is the same as that of the second embodiment and can exhibit similar operational effects.

### Fourth Embodiment

The present embodiment illustrates an example of a photoelectric conversion device provided with a light-shielding layer that absorbs visible light. Relative to the configurations shown in the first and second embodiments, the photoelectric conversion device 100 of the present embodiment further includes a light-shielding layer 112 that absorbs visible light. The following description focuses on portions that differ from the first and second embodiments, and descriptions common to those embodiments are omitted as appropriate.

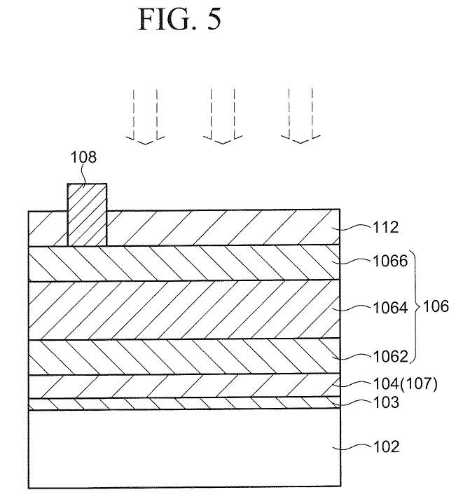

FIG. 5 is a cross-sectional view of a photoelectric conversion device 100 according to the present embodiment. The photoelectric conversion device 100 has a structure similar to the first embodiment, with a base insulating layer 103, an orientation control layer 104, and a photoelectric conversion structure 106 (first compound semiconductor layer 1062, second compound semiconductor layer 1064, third compound semiconductor layer 1066) stacked on top of an amorphous substrate 102. FIG. 5 illustrates a case where the light-receiving surface of the photoelectric conversion device 100 is on the side of the third compound semiconductor layer 1066 of the photoelectric conversion structure 106. A light-shielding layer 112 is provided on the light-receiving side, overlapping the photoelectric conversion structure 106.

The light-shielding layer 112 has properties of absorbing visible light and transmitting infrared radiation. The light-shielding layer 112 is formed of a crystalline III-V compound semiconductor material, as is the photoelectric conversion structure 106. The photoelectric conversion structure 106 is formed of multiple compound semiconductor layers, among which the second compound semiconductor layer 1064 serves as the light-absorbing layer; preferably, the light-shielding layer 112 absorbs visible light while exhibiting high transmittance to light in the infrared wavelength band that the second compound semiconductor layer 1064 absorbs. From the viewpoint of a bandgap, it is preferable that the bandgap Eg1 of the compound semiconductor forming the light-shielding layer 112 be greater than the bandgap Eg2 of the compound semiconductor forming the second compound semiconductor layer 1064 (Eg1>Eg2).

Such control of the bandgaps of the light-shielding layer 112 and the second compound semiconductor layer 1064 can be achieved by selecting different combinations of constituent elements for the compound semiconductor materials forming the respective layers, or by using the same constituent elements while varying their composition ratios.

For example, when both the light-shielding layer 112 and the second compound semiconductor layer 1064 are formed of gallium arsenide antimonide (GaAsSb), the bandgap can be varied by changing the composition ratio of arsenic (As) and antimony (Sb). Specifically, by increasing the ratio of arsenic (As) in the light-shielding layer 112 compared to that in the second compound semiconductor layer 1064 and increasing the ratio of antimony (Sb) in the second compound semiconductor layer 1064 compared to that in the light-shielding layer 112, a relationship can be achieved where the band gap is Eg1>Eg2. Stated differently, when the light-shielding layer 112 has a composition Gax1Asy1Sbz1 (where x1+y1+z1=1) and the second compound semiconductor layer 1064 has a composition Gax2Asy2Sbz2 (where x2+y2+z2=1), setting y1>y2 and z1<z2 yields Eg1>Eg2.

When the second compound semiconductor layer 1064 is formed of indium nitride (InN) or indium gallium nitride (InGaN), the light-shielding layer 112 can be formed of aluminum indium nitride (AlInN) or indium gallium nitride (InGaN). In this example, although both the light-shielding layer 112 and the second compound semiconductor layer 1064 are nitride-based crystalline III-V compound semiconductors, the relationship Eg1>Eg2 can be achieved by setting the indium (In) fraction in the light-shielding layer 112 lower than that in the second compound semiconductor layer 1064.

The upper limit of the band gap in the light-shielding layer 112 is preferably about 1.65 eV (750 nm). If the band gap Eg1 exceeds this value, it is undesirable because it transmits light in the visible light range. It is also preferable that the difference between the bandgap Eg1 of the light-shielding layer 112 and the bandgap Eg2 of the second compound semiconductor layer 1064 be 0.1 eV or greater.

It is preferable that the light-shielding layer 112 be crystalline, as is the second compound semiconductor layer 1064. With a crystalline light-shielding layer, defect density can be reduced, optical absorption near the band edge (tail absorption) can be suppressed, and the transmittance of light with photon energy below the bandgap Eg1 can be increased.

Thus, it is possible to prevent light in the visible light range from entering the photoelectric conversion structure 106 (or reduce the intensity of light in the visible light range) by providing a light-shielding layer 112 on the light-receiving side of the photoelectric conversion structure 106. As a result, the noise of the photoelectric conversion device 100 can be reduced and the sensitivity can be improved.

The light-shielding layer 112 may be undoped and highly resistive. Accordingly, it is preferable to provide the second electrode 108 so that it penetrates the light-shielding layer 112 and contacts the third compound semiconductor layer 1066. Conversely, the light-shielding layer 112 may be doped to have the same conductivity type as the third compound semiconductor layer 1066. In that case, the second electrode 108 may be provided in contact with the surface of the light-shielding layer 112.

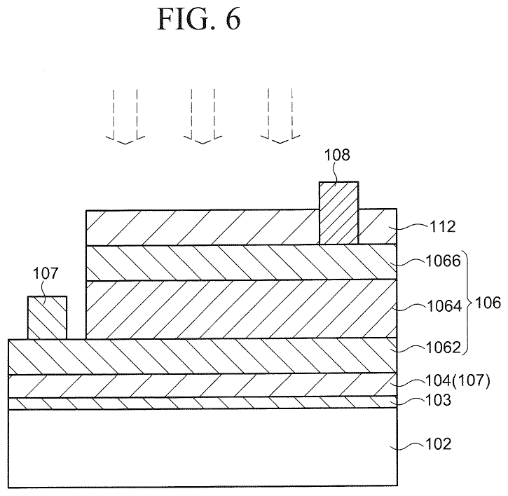

FIG. 6 shows a photoelectric conversion device 100 having the same configuration as the photoelectric conversion device shown in the second embodiment, and furthermore, the light-shielding layer 112 that absorbs light in the visible light region is provided on top of the photoelectric conversion structure 106. As shown in FIG. 6, it is possible to reduce the intensity of visible light incident on the second compound semiconductor layer 1064 and infrared light incident on the third compound semiconductor layer 1066 by selectively providing the light-shielding layer 112 on top of the third compound semiconductor layer 1066.

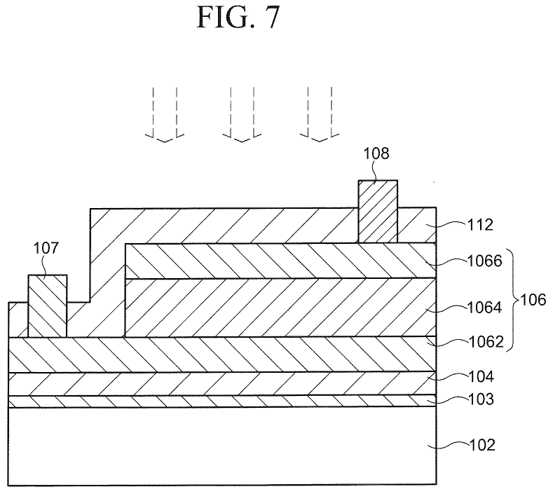

FIG. 7 shows a photoelectric conversion device having a configuration similar to that of the second embodiment; the light-shielding layer 112 that absorbs visible light is provided continuously from the top surface of the third compound semiconductor layer 1066, across the side surfaces of the third compound semiconductor layer 1066 and the second compound semiconductor layer 1064, to the top surface of the first compound semiconductor layer 1062. Put another way, the photoelectric conversion device 100 shown in FIG. 7 has a structure in which the light-shielding layer 112 is provided to cover not only the top surface of the photoelectric conversion structure 106 but also the top surface and sides exposed by etching. It is possible to reduce the influence of scattered light incident from the side surface of the photoelectric conversion structure 106 by having such a structure of the light shielding layer 112, thereby improving the sensitivity of the photoelectric conversion device 100.

The photoelectric conversion device 100 of the present embodiment has a light shielding layer 112 that absorbs visible light on the photosensitive surface, which prevents visible light from entering the photoelectric conversion structure 106, thereby improving the sensitivity when detecting infrared light. Since the light shielding layer 112 is formed of a compound semiconductor, it can be continuously deposited from the photoelectric conversion structure 106. In other words, the productivity of the photoelectric conversion device 100 can be improved because the light-shielding layer 112 is formed with a thin film of a compound semiconductor. In addition, since the light-shielding layer 112 is formed directly on top of the photoelectric conversion structure 106, the photoelectric conversion device 100 can be made smaller.

The photoelectric conversion element 100 shown in the first to fourth embodiments can be applied to the measurement of blood glucose levels by designing it to be sensitive to infrared rays in the band of wavelengths from 1.3 μm to 1.9 μm. The photoelectric conversion element 100 can be made thinner and smaller because the photoelectric conversion structure 106 is formed with a compound semiconductor having crystallinity deposited on an amorphous substrate 102. Thereby, the photoelectric conversion device 100 can be made so that it does not affect the appearance when mounted in portable electronic devices such as smart watches, and the functionality of said electronic devices can be improved and their design can be enhanced.

Although the above description has focused on a photoelectric conversion device usable as an infrared sensor, the device disclosed herein can also serve as a photosensor for light other than infrared, so long as the light falls within a wavelength band that the photoelectric conversion structure can convert.

The various configurations of the photoelectric conversion device exemplified as embodiments of the present invention may be combined with one another as appropriate insofar as they are not mutually inconsistent. Moreover, based on the photoelectric conversion device disclosed in this specification and the drawings, implementations in which a person skilled in the art has appropriately added, removed, or modified components, or has added, omitted, or changed process steps or conditions, are also included within the scope of the present invention, so long as they embody the gist of the invention.

It is understood that other advantageous effects different from the advantageous effects provided by the embodiments disclosed herein, which are obvious from the description herein or which can be easily foreseen by those skilled in the art, are naturally provided by the present invention.

What is claimed is:

1. A photoelectric conversion device, comprising:
an amorphous substrate;
an orientation control layer on the amorphous substrate; and
a photoelectric conversion structure disposed on the orientation control layer and comprising a crystalline III-V compound semiconductor.

2. The photoelectric conversion device according to claim 1, wherein the crystalline III-V compound semiconductor has a band gap of 1.66 eV or less.

3. The photoelectric conversion device according to claim 1, wherein the photoelectric conversion structure includes a p-n junction or a p-i-n structure.

4. The photoelectric conversion device according to claim 1, wherein the orientation control layer has a crystal oriented along the c-axis and is conductive or insulating.

5. The photoelectric conversion device according to claim 1, further comprising a light-shielding layer disposed on a light-incident side of the photoelectric conversion structure and configured to block at least visible light.

6. The photoelectric conversion device according to claim 5, wherein the light-shielding layer covers an upper surface and a side surface of the photoelectric conversion structure.

7. The photoelectric conversion device according to claim 5, wherein the light-shielding layer comprises a III-V compound semiconductor.

8. The photoelectric conversion device according to claim 1, wherein the photoelectric conversion structure has crystallinity and comprises at least one material selected from the group of InGaAs, InAsN, InAsP, InGaN, GaAsP, InAsN, GaAsSb, and InN.

9. The photoelectric conversion device according to claim 7, wherein the light-shielding layer has crystallinity and comprises at least one material selected from the group of GaAsSb, InGaN, and AlInN.

10. The photoelectric conversion device according to claim 1, wherein the amorphous substrate is a glass substrate or a resin substrate.
